(19) United States
(12) Patent Application Publication
(10) Pub. No.: US 2015/0123703 A1
(43) Pub. Date: May 7, 2015

(54) LOGIC GATE AND A CORRESPONDING METHOD OF FUNCTION

(71) Applicant: CONSIGLIO NAZIONALE DELLE RICERCHE, Roma (IT)

(72) Inventors: Valentin Alek Dediu, Bologna (IT); Mirko Prezioso, Bologna (IT); Alberto Riminucci, Rimini (IT); Ilaria Bergenti, Felino (IT); Patrizio Graziosi, Vignola (IT)

(73) Assignee: CONSIGLIO NAZIONALE DELLE RICERCHE, Roma (IT)

(21) Appl. No.: 14/349,868

(22) PCT Filed: Oct. 5, 2012
(86) PCT No.: PCT/IB2012/055393

§ 371 Date: Apr. 4, 2014

(30) Foreign Application Priority Data
Oct. 6, 2011 (IT) B02011A000571

(51) Int. Cl. H03K 19/18

(52) U.S. Cl. CPC H03K 19/18
USPC 326/38

(57) ABSTRACT

A logic gate (1) comprising a spintronic memristor device (2), which has two spin-polarized magnetic electrodes (3, 4) for injecting and/or receiving a spin-polarized current and a layer of material (5) interposed between the two electrodes (3, 4) for transporting the spin-polarized current from one electrode to the other. The layer of material (5) is composed of a layer of organic semiconductor that is able to endow the spintronic memristor device (2) with at least two non-volatile electrical resistance states (RH, RL), each of which can be selected by applying a voltage to the electrodes (3, 4) that reaches or exceeds a respective voltage threshold (VT1, VT2) and, in at least a first resistance state (RH) of which, the spintronic memristor device (2) does not present a magnetoresistive effect.

### TECHNICAL FIELD

The present invention relates to a logic gate and a method of operation of this logic gate.

### BACKGROUND ART

The information and communications technologies are always seeking increasingly smaller digital electronic devices with increasingly lower consumption. The recent development of so-called “spintronic” devices has enabled the industry of mass consumer products to be revolutionized with regard to data storage. A passive spintronic device comprises two spin-polarized magnetic electrodes for injecting and/or receiving a spin-polarized current and a charge transport medium interposed between the two electrodes for transporting the spin-polarized current from one electrode to the other. In this document, the term passive device is intended as a device where the electrical output power is less than the electrical input power. The parallel or antiparallel alignment of magnetization of the two electrodes produces a different measurable electrical resistance between the electrodes. This effect, which is known as the giant magnetoresistance or tunnel magnetoresistance effect, is advantageously exploited in the read heads of modern hard disks.

However, known passive spintronic devices do not permit the creation of logic gates, or rather those base elements that, opportunely combined by the hundreds or thousands in logic circuits, permit the creation of digital memories and processing units.

### DISCLOSURE OF INVENTION

The object of the present invention is to provide, in a simple and inexpensive manner, a logic gate comprising a spintronic device, and in particular a spintronic memristor device.

In accordance with the present invention, a logic gate and a logic gate operation method are provided as defined in the appended claims.

### BRIEF DESCRIPTION OF THE DRAWINGS

The present invention will now be described with reference to the attached drawings, which illustrate a non-limitative embodiment, where:

FIG. 1 schematically shows a logic gate made according to the invention;

FIGS. 2 to 5 show the electrical and magnetic behaviour of a device of the logic gate in FIG. 1; and

FIGS. 6 and 7 show the truth tables of two fundamental logic functions reproduced with the logic gate in FIG. 1.

### BEST MODE FOR CARRYING OUT THE INVENTION

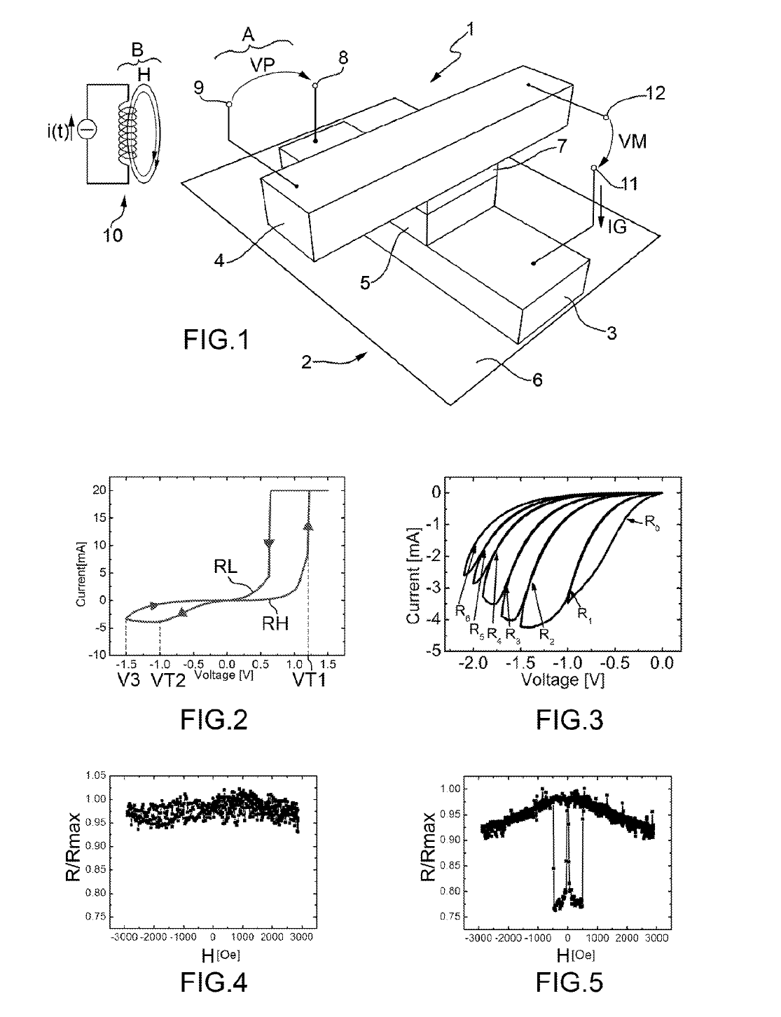

In FIG. 1, reference numeral 1 generically indicates, as a whole, a logic gate comprising a single passive spintronic memristor device 2, which is shown a very schematic manner and comprises two spin-polarized magnetic electrodes 3 and 4 for injecting and/or receiving a spin-polarized current and a spin-polarized charge transport medium interposed between the two electrodes 3 and 4 for transporting the spin-polarized current from one electrode to the other. The charge transport medium comprises a layer of material 5 that endows the spintronic memristor device 2 with at least two stable and non-volatile electrical resistance states, which can be selected by applying a voltage to the electrodes 3 and 4 that reaches or exceeds two respective voltage thresholds and are such that the spintronic memristor device 2 does not present a magnetoresistive effect in at least one of the electrical resistance states.

In particular, the spintronic memristor device 2 comprises a substrate 6 of neodymium gallate (NGO) or strontium titanate (STO), upon which electrode 3, the layer of material 5 and electrode 4 are deposited, in the order just indicated. The electrodes 3 and 4 are made of two different magnetic materials, i.e. having different coercive magnetic fields. In particular, electrode 3 is composed of a layer of spin-polarized magnetic oxide and electrode 4 is composed of a layer of spin-polarized magnetic metal or metal alloy. For example, electrode 3 is composed of a layer of lanthanum strontium manganite, the chemical formula of which is La_{0.7}Sr_{0.3}Mn0₃ (LSMO) and electrode 4 is composed of a layer of cobalt (Co). The layer of material 5 is composed of a layer of organic semiconductor, and in particular of aluminium quinoline, the abbreviated chemical formula of which is Alq3. The spintronic memristor device 2 also comprises a thin layer of aluminium oxide 7 (AlOₓ) interposed between the electrode 4 and the layer of material 5. The electrode 3, the layer of material 5, the layer of aluminium oxide 7 and electrode 4 are consequently deposited in this order, one on top of the other.

The electrodes 3 and 4 have a thickness of between 10 and 50 nm. The layer of organic semiconductor 5 has a thickness of between 100 and 250 nm. The layer of aluminium oxide 7 has a thickness of between 1 and 3 nm, i.e. relatively thin with respect to the other layers 3, 4 and 7 because its only purpose is to improve the growth of the layer of cobalt 4 on the layer of organic semiconductor 5.

The spin-polarized current that passes through the spintronic memristor device 2 is composed of spin-polarized charge carriers, which are injected, via the so-called “tunnel” effect, by an electrode 3 or 4 into the layer of organic semiconductor 5, propagate, via the so-called “diffusive-hopping” effect, across the layer of organic semiconductor 5 and are received, via the “tunnel” effect, by the other electrode 4 or 3.

FIG. 2 shows a curve of the spin-polarized current measurable at the electrodes 3 and 4 as a function of the voltage applied to the electrodes 3 and 4. Electrode 4 is the reference electrode for applying the voltage. The graph in FIG. 2 clearly shows that the spintronic memristor device 2 has a non-volatile bistable behaviour, i.e. characterized by two stable electrical resistance states for small voltage values, or rather an absolute value lower than 0.5 V, applied to the electrodes 3 and 4. In other words, the device 2 behaves like a memristor device. The two resistance states comprise a high-resistance state, represented by the portion of the curve indicated by RH, and a low-resistance state, represented by the portion of the curve indicated by RL. Starting from the high-resistance state RH, by applying a positive voltage to the electrodes 3 and 4 that reaches or exceeds a positive first voltage threshold VT1 equal to approximately +1.2 V, the spintronic memristor device 2 switches to the low-resistance state RL. The spintronic memristor device 2 switches back to the high-resistance state RH only by applying a negative voltage to the electrodes 3 and 4 that reaches or exceeds, in absolute value, a negative second voltage threshold VT2 equal to approximately −1 V. In particular, on the curve in FIG. 2, return to the high-resistance state RH takes place when the voltage at the electrodes 3 and 4 reaches a value V3, of programming so to speak, equal to approximately −1.5 V. Return to the high-resistance state RH, or rather passage from the RL curve portion to the RH curve portion, becomes evident as soon as the value of the voltage at the electrodes 3 and 4 is brought back towards 0 V.

It is worthwhile to underline yet again that the spintronic memristor device 2 can present more than two electrical resistance states that can be selected via respective voltage values at the electrodes 3 and 4. In this regard, FIG. 3 shows a series of curves of the spin-polarized current measurable at the electrodes 3 and 4 in function of the negative voltage applied at the electrodes 3 and 4, these curves revealing the switching between seven different resistance states R0-R6 of increasing value, starting from a first low-resistance state R0, passing five intermediate resistance states R1-R5 in sequence and arriving at a high-resistance state R6. The curves are obtained by varying the voltage at the electrodes 3 and 4 so as to reach the seven increasing programming voltage values in sequence, returning to 0 V, however, before reaching the next programming voltage. In the example in FIG. 3, switching between the states of increasing resistance R1-R0 occurs with the following programming voltage values:
from R0 to R2 at approximately −1 V;
from R1 to R2 at approximately −1.5 V;
from R2 to R3 at approximately −1.75 V;
from R3 to R4 at approximately −1.9 V;
from R4 to R5 at approximately −2 V; and
from R5 to R6 at approximately −2.1 V.

Taking the voltage applied to the electrodes 3 and 4 towards more negative values does not give a further increase in electrical resistance. It should be noted that the programming voltage value of the R6 resistance state does not coincide with the programming voltage value of the high-resistance state RH because the curves in FIG. 3 were obtained at a different temperature from that at which the curve in FIG. 2 was obtained.

FIGS. 4 and 5 illustrate the electrical resistance R measured at the electrodes 3 and 4, normalized to the maximum measured value Rmax, as a magnetic field H applied to the electrodes 3 and 4 varies, when the spintronic memristor device 2 is in the high-resistance state RH and, respectively, in the low-resistance state RL. The curves in FIGS. 4 and 5 were create by varying the magnetic field H, first from a maximum positive value to a maximum negative value, passing through zero, and then from the maximum negative value to the maximum positive value, always passing through zero, and measuring the electrical resistance at the electrodes 3 and 4 by applying a measuring voltage of approximately −0.1 V to them. The saturation of both materials of the electrodes 3 and 4 corresponds to the maximum positive and negative magnetic field H values. From the figures, it is possible to observe a substantial absence of magnetoresistive effect in the high-resistance state RH (FIG. 4) and the presence of a significant magnetoresistive effect, equal to approximately 22%, in the low-resistance state RL (FIG. 5). The magnetoresistive effect manifests itself with an abrupt drop in the electrical resistance for magnetic field H values is in the range of the coercive magnetic fields of the two electrodes 3 and 4, i.e. for magnetic field H values that align the magnetizations of the electrodes 3 and 4 in antiparallel.

To observe a magnetoresistive effect, it is necessary to have two electrodes 3 and 4 that are spin polarized, but this is still not sufficient. From the literature, it is known that there are other conditions that must be satisfied to be able to observe a magnetoresistive effect, such as very precise ratios between the resistances of the electrodes 3 and 4 and the resistance of the charge transport medium for example. In the case where the charge transport medium comprises a layer of inorganic semiconductor, these resistance ratios must not less than 0.001 for an ideal quality of the spin-polarized electrodes (99% with respect to the technologically achievable 30-40%). Consequently, a strong change in the resistance of at least one of the components of the device 2 can “switch off” the magnetoresistance.

Essentially, by applying a positive voltage to the electrodes 3 and 4 that is greater than voltage threshold VT1, the spintronic memristor device 2 switches to the low-resistance state RL and consequently “switches on” the magnetoresistance of the spintronic memristor device 2; instead, by applying a negative voltage to the electrodes 3 and 4 that is less than voltage threshold VT2, the spintronic memristor device 2 switches to the high-resistance state RH and consequently “switches off” the magnetoresistance of the spintronic memristor device 2. These effects of switching the magnetoresistance on and off are reproducible and experimentally observable.

With reference to FIG. 1 again, the logic gate 1 comprises a pair of electrical terminals 8 and 9, respectively connected to the two electrodes 3 and 4 for applying a programming voltage VP to the latter so as to select one of the resistance states RH and RL, and a magnetic field source 10 for applying a magnetic field H to the electrodes 3 and 4 so as to align the magnetization of the electrodes 3 and 4 in parallel or antiparallel. The programming voltage VP represents a first input signal A of the logic gate 1 and the magnetic field H represents a second input signal B of the logic gate 1. The magnetic field source 10 comprises, for example, a coil powered by a variable voltage generator. The logic gate 1 comprises a further pair of electrical terminals 11 and 12 connected to the two electrodes 3 and 4 to enable detection and measurement of a current IG at the electrodes 3 and 4. Current IG represents the output signal of the logic gate 1.

The logic gate 1 enables the truth table of any fundamental logic function to be reproduced according to how the resistance states RH and RL are encoded, in binary logic, the alignments in parallel and antiparallel of the magnetizations of the electrodes 3 and 4 and the values of current IG with respect to a predetermined current threshold IT.

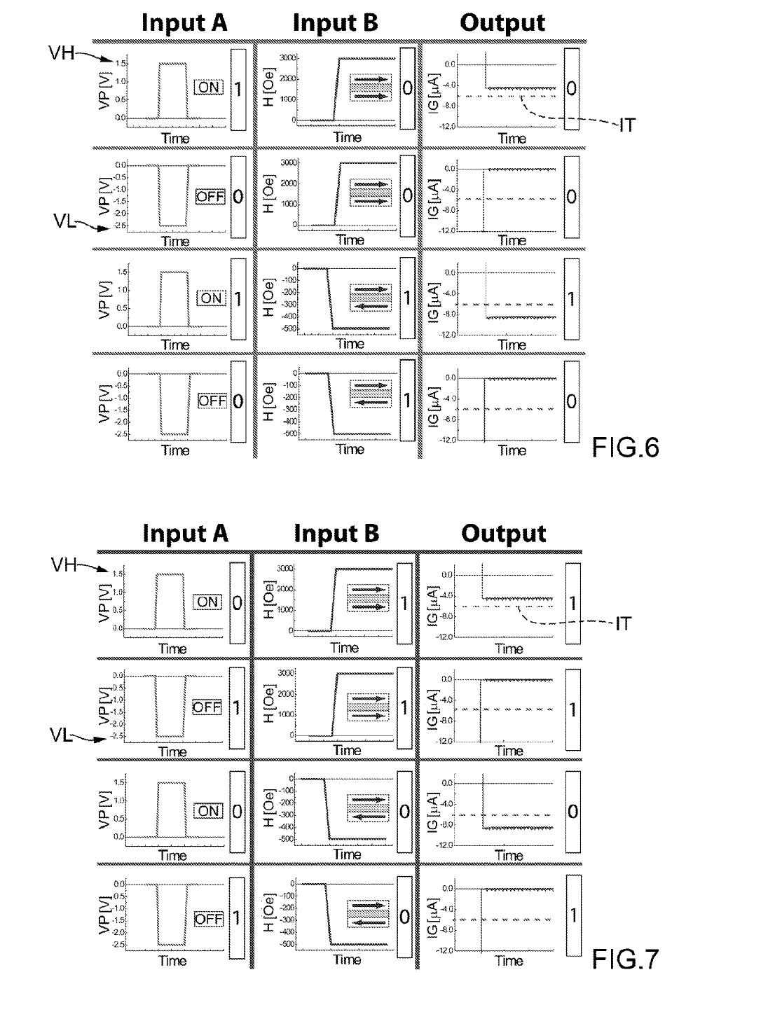

Operation of the logic gate 1 as an AND gate and as an OR gate is illustrated schematically in FIGS. 6 and 7. In both FIGS. 6 and 7, the programming voltage VP represents the input signal A of the logic gate 1, the magnetic field H represents the input signal B of the logic gate 1 and current IG represents the output signal of the logic gate 1. The method of operation of the logic gate 1 is described in detail below, with reference to both FIGS. 6 and 7.

First of all, the programming voltage VP is applied to terminals 8 and 9 to select one of the resistance states RH and RL and, in consequence, to “switch on” or “switch off” the magnetoresistance of the spintronic memristor device 2. The programming voltage VP is a voltage pulse of predetermined duration that assumes two voltage values VH and VL. Voltage value VH is approximately equal to +1.5 V, i.e. greater than voltage threshold VT1, to “switch on” the, magnetoresistance and voltage value VL is approximately equal to −2.5 V, i.e. less than voltage threshold VT2, to “switch off” the magnetoresistance.

Following application of the programming voltage VP, the magnetic field source 10 is switched on and controlled to apply a magnetic field H such as to align the magnetization of the electrodes 3 and 4 in the desired manner. In the example shown in FIGS. 6 and 7, the magnetic field H is brought to a maximum positive value Hmax approximately equal to +3000 Oe, or 240000 A/m, passing through zero, to align the magnetizations of the electrodes 3 and 4 in parallel, or is brought to a negative value HL in the range of the coercive magnetic fields of the materials of the two electrodes 3 and 4, and in particular approximately equal to −500 Oe, to align the magnetizations of the electrodes 3 and 4 in antiparallel.

Finally, after application of the magnetic field H, the current IG at terminals 11 and 12 is measured by applying a measuring voltage VM (FIG. 1) of approximately −0.1 V to them. The measuring voltage VM is negative to maximize the magnetoresistance. The logic output signal of the logic gate 1, or rather the logic value “0” or “1” output from the logic gate 1, is generated on the basis of a comparison between the measured current IG and current threshold IT.

If the magnetoresistance of the spintronic memristor device 2 is “on” (low-resistance state RL), then the intensity of current IG depends of the parallel or antiparallel alignment of the magnetization of the electrodes 3 and 4. In particular, the current IG that is measured with the magnetizations aligned in parallel is approximately twice that which is measured with the magnetizations aligned in antiparallel. Instead, if the magnetoresistance of the spintronic memristor device 2 is “off” (high-resistance state RH), then the current IG is at least an order of magnitude smaller, i.e. at least ten times smaller, than the current IG in the low-resistance state RL. The current threshold IT has an intermediate value with respect to the measurable current IG values when the magnetoresistance is on. In the example shown in FIGS. 6 and 7, on applying a measuring voltage VM approximately equal to −100 mV, current IG is approximately equal to −4 μA with the magnetizations aligned in parallel and approximately equal to −8 μA with the magnetizations aligned in antiparallel. The current threshold IT is approximately equal to −6 μA.

With reference to FIG. 6, the logic gate 1 reproduces the truth table of an AND gate when the voltage values VH and VL, and therefore the respective resistance states RL and RH, are respectively encoded as logic values “1” and “0”, the parallel and antiparallel alignment of the magnetizations of the electrodes 3 and 4 are respectively encoded as logic values “0” and “1” and only current IG values below the current threshold IT are encoded as logic value “1”.

With reference to FIG. 7, the logic gate 1 reproduces the truth table of an OR gate when the voltage values VH and VL, and therefore the respective resistance states RL and RH, are respectively encoded as logic values “0” and “1”, the parallel and antiparallel alignment of the magnetizations of the electrodes 3 and 4 are respectively encoded as logic values “1” and “0” and only current IG values greater than the current threshold IT are encoded as logic value “1”.

From the foregoing description, it is evident that by changing the logic encoding of the resistance states RL and RH of the parallel and antiparallel alignment of the magnetizations of the electrodes 3 and 4 and the current IG values with respect to the current threshold IT and/or choosing an opportune value for the current threshold IT, it is possible to reproduce the truth table of other fundamental logic functions, for example NAND, EXOR, etc.

Although the above-described invention makes special reference to a quite specific embodiment, it should not be considered as limited this embodiment, but with all those variants, changes or simplifications that would be evident to an expert in the field falling within its scope, such as the following examples.

According to a further embodiment of the present invention, the electrode 3 is composed of a layer of ferromagnetic manganite having the chemical formula RE₁₋ₓMₓMn0₃, where RE is a rare earth, in particular selected from a group comprising lanthanum (La) and neodymium (Nd), M is a divalent metal, selected from the alkaline earth group and, in particular, selected from a group comprising calcium (Ca), strontium (Sr) and lead (Pb), and the value of x is between 0.15 and 0.4.

According to a further embodiment of the present invention, the electrode 4 is made of another metal or metal alloy selected from a group comprising iron (Fe), nickel (Ni), cobalt (Co) and respective alloys, or a ferromagnetic oxide selected from a group comprising iron oxides and mixed oxides of ferro-cobalt and ferro-nickel.

According to a further embodiment of the present invention, the layer of aluminium oxide 7 is absent.

According to a further embodiment of the present invention, the organic semiconductor is selected from a group comprising pi-conjugated organic semiconductors, quinolines, polycyclic aromatic hydrocarbons, ftalocianines, thiophenes and fullerenes.

According to a further embodiment of the present invention, the voltage values VH and VL, in having to depend on the voltage thresholds VT1 and VT2 that, in turn, are defined by the materials with which the spintronic memristor device 2 is made, are generally, in absolute value, greater than 1 V and, in particular, voltage value VH is greater than +1 V and voltage value VL is less than −1 V.

According to a further embodiment of the present invention, the measuring voltage VM has an absolute value, in general between 10 mV and 500 mV, which depends on the materials with which the spintronic memristor device 2 is made.

The main advantage of the above-described logic gate 1 is to enable reproducing the truth table of any fundamental logic function with a single spintronic memristor device 2. Furthermore, the logic gate 1 has very low power consumption thanks to the fact that it can be powered by input signals (VP) having low voltage values (approximately 1 V).

1. A logic gate comprising a spintronic memristor device (2), which comprises two spin-polarized magnetic electrodes (3, 4) for injecting and/or receiving a spin-polarized current and a charge transport medium (5) interposed between the two electrodes (3, 4) for transporting the spin-polarized current from one electrode to the other; said charge transport medium comprising a material (5) that is able to endow the spintronic memristor device (2) with at least two non-volatile electrical resistance states (RH, RL), each resistance state (RH, RL) being selectable by applying a voltage to the electrodes (3, 4) that reaches or exceeds a voltage threshold (VT1, VT2) associated to the resistance state (RH, RL) and, in at least a first resistance state (RH) of said two resistance states (RH, RL), said spintronic memristor device (2) not presenting a magnetoresistive effect.

2. A logic gate according to claim 1, and comprising a first pair of electrical terminals (8, 9), which are respectively connected to the two electrodes (3, 4) to enable the application of a programming voltage (VP) to the latter so as to select one of said electrical resistance states (RH, RL), said programming voltage (VP) representing a first input signal of the logic gate (1), and magnetic field source means (10) to apply a magnetic field (H) to the electrodes (3, 4) so as to align the magnetization of the electrodes (3, 4), said magnetic field (H) representing a second input signal of the logic gate (1).

3. A logic gate according to claim 2 and comprising a second pair of electrical terminals (11, 12) respectively connected to the two electrodes (3, 4) to enable the measurement of a current (IG) at the electrodes (3, 4), the measured current (IG) representing an output signal of the logic gate (1).

4. A logic gate according to claim 1, wherein said material is selected from a group comprising pi-conjugated organic semiconductors, quinolines, polycyclic aromatic hydrocarbons, ftalocianines, thiophenes and fullerenes.

5. A logic gate according to claim 1, wherein said material is an organic semiconductor (5).

6. A logic gate according to claim 5, wherein the organic semiconductor (5) is composed of aluminium quinoline.

7. A logic gate according to claim 1, wherein one of said electrodes (3, 4) is made of ferromagnetic manganite having the chemical formula RE₁₋ₓMₓMn0₃, where RE is a rare earth selected from a group comprising lanthanum and neodymium, M is a divalent metal selected from a group comprising calcium, strontium and lead, and the value of x is between 0.15 and 0.4.

8. A logic gate according to claim 1, wherein one of said electrodes (3, 4) is made of lanthanum strontium manganite.

9. A logic gate according to claim 1, wherein one of said electrodes (3, 4) is made of a metal or a metal alloy selected from a group comprising iron, nickel, cobalt and respective alloys, or a ferromagnetic oxide selected from a group comprising iron oxides and mixed oxides of ferro-cobalt and ferro-nickel.

10. A logic gate according to claim 1, wherein one of said electrodes (3, 4) is made of cobalt.

11. A logic gate according to claim 1, wherein said charge transport medium comprises a layer of organic semiconductor (5); said spintronic memristor device (2) comprising a layer of aluminium oxide (7) interposed between the layer of organic semiconductor (5) and said second electrode (4).

12. A method of operation of a logic gate comprising a spintronic memristor device (2), which comprises two spin-polarized magnetic electrodes (3, 4) for injecting and/or receiving a spin-polarized current and a charge transport medium (5) interposed between the two electrodes (3, 4) for transporting the spin-polarized current from one electrode to the other; said charge transport medium comprising a material (5) that is able to endow the spintronic memristor device (2) with at least two non-volatile electrical resistance states (RH, RL), each resistance state (RH, RL) being selectable by applying a voltage to the electrodes (3, 4) that reaches or exceeds a voltage threshold (VT1, VT2) associated to the resistance state (RH, RL) and, in at least a first resistance state (RH) of said two resistance states (RH, RL), said spintronic memristor device (2) not presenting a magnetoresistive effect; the method comprising, in the following order:
applying a programming voltage (VP) to the electrodes (3, 4) to select one of the electrical resistance states (RH, RL), the programming voltage (VP) representing a first input signal of the logic gate (1);
applying a magnetic field (H) to the electrodes (3, 4) to align the magnetization of the electrodes (3, 4), the magnetic field (H) representing a second input signal of the logic gate (1); and
measuring a current (IG) at the electrodes (3, 4), the measured current (IG) representing an output signal of the logic gate (1).

13. A method according to claim 12 and comprising:
generating a logic output signal of the logic gate (1) based on a comparison between said measured current (IG) and a predetermined current threshold (IT).

14. A method according to claim 12, wherein said material is an organic semiconductor (5).

15. A method according to claim 12, wherein said organic semiconductor (5) is composed of aluminium quinoline.

16. A method according to claim 12, wherein a first electrode (3) of said electrodes is made of lanthanum strontium manganite and the second (4) of said electrodes is made of cobalt.

17. A method according to claim 12, wherein said programming voltage (VP) assumes two voltage values (VH, VL), each of which is associated with a respective one of said electrical resistance states (RH, RL) and is chosen as a function of said respective voltage threshold (VT1, VT2) and encoded with a respective logic value.

18. A method according to claim 12, wherein a first (RH) of said electrical resistance states (RH, RL) is the highest electrical resistance state.

19. A method according to claims 17, wherein a first (RH) of said electrical resistance states (RH, RL) is the highest electrical resistance state, a first (VL) of said two voltage values (VH, VL) is lower than −1 V and enables selection of the first electrical resistance state (RH), and a second (VH) of said two voltage values is higher than +1 V and enables selection of the second electrical resistance state (RL).

20. A method according to claim 12, wherein the magnetization of the electrodes (3, 4) can be aligned in parallel or antiparallel; each of the parallel and antiparallel alignments being encoded with a respective logic value.

21. A method according to claim 12, wherein measuring the current (IG) at the electrodes (3, 4) comprises:
applying a measuring voltage (VM) to the electrodes (3, 4), the absolute value of which is in the range from 10 mV to 500 mV.
